(19) United States
(12) Patent Application Publication
(10) Pub. No.: US 2015/0185530 A1
(43) Pub. Date: Jul. 2, 2015

(54) TFT Array Substrate, Liquid Crystal Panel and LCD

(71) Applicant: SHENZHEN CHINA STAR OPTOELECTRONICS TECHNOLOGY CO., LTD., Shenzhen (CN)

(72) Inventors: Yanfeng Fu, Shenzhen City (CN); Dongzi Gao, Shenzhen City (CN)

(21) Appl. No.: 14/234,627

(22) PCT Filed: Oct. 21, 2013
(86) PCT No.: PCT/CN2013/085595

§ 371 Date: Jan. 23, 2014

(30) Foreign Application Priority Data
Sep. 26, 2013 (CN) 201310443447.1

(51) Int. Cl. G02F 1/1362; H01L 27/12; H01L 23/544; G02F 1/1335

(52) U.S. Cl. CPC G02F 1/13624; G02F 1/1336; H01L 27/1214; H01L 23/544

(57) ABSTRACT

The present invention proposes a TFT array substrate, a liquid crystal panel and LCD device. The TFT array substrate includes a transparent substrate, comprising a non-pixel area and a pixel area; multiple TFTs arranged in array in the pixel area; and an alignment mark in the non-pixel area. The alignment mark which is not covered by any insulating material layer is exposed because the insulating material layer on the alignment mark is removed. Therefore, it prevents from an alignment difference caused by a film-color difference between the second and the fourth insulating material layers on the alignment marks caused by uneven film thickness if the distance between the alignment mark in the non-pixel area and the brink of the transparent substrate is narrower than insulating material protecting area (i.e. the alignment mark is out of the insulating material layer protecting area).

### BACKGROUND OF THE INVENTION

1. Field of the Invention

The present invention relates to a liquid crystal display (LCD) field, more particularly, to a thin film transistor (TFT) array substrate, a liquid crystal panel and an LCD.

2. Description of the Prior Art

Alignment marking is crucial in a producing process for a liquid crystal panel. For instance, it needs to read a alignment mark position when a measuring instrument coordinate-sets and an exposure machine exposure aligns, or confirms the box position through the alignment mark when assembling a TFT array substrate and a color filter substrate. It designs alignment marks in the surrounding of a TFT array substrates in the prior art. Most of the alignment marks are produced by gate metals and then are deposited a second layer of insulation film (with materials like SiNx) and a fourth layer of insulation film (with materials like SiNx).

The alignment marks on the TFT array substrate are generally designed on a brink of glass substrates and are closer to the brink with being compacter in the arrangement of the glass substrates. A film-color difference between the second and the fourth insulation film layers on the alignment marks caused by uneven film thickness attributes to failure of seizing alignment mark, board alarm, product disposal, etc in continuous processes if the distance between the alignment marks and the brink of the glass substrate is narrower than insulation film protecting area.

### SUMMARY OF THE INVENTION

According to the present invention, a thin film transistor (TFT) array substrate comprises: a transparent substrate, comprising a non-pixel area and a pixel area; a plurality of TFTs arranged in array in the pixel area; and an alignment mark in the non-pixel area.

In one aspect of the present invention, an insulating material layer covers the non-pixel area excluding the alignment mark.

In another aspect of the present invention, an insulating material layer covers the non-pixel area excluding the alignment mark and a surrounding area close to the alignment mark.

In still another aspect of the present invention, the non-pixel area does not comprise insulating layer material. According to the present invention, a liquid crystal panel comprising a color filter substrate, a thin film transistor (TFT) array substrate and a liquid crystal layer between the color filter substrate and the TFT array substrate is provided. The TFT array substrate comprises: a transparent substrate, comprising a non-pixel area and a pixel area; a plurality of TFTs arranged in array in the pixel area; and an alignment mark in the non-pixel area.

In one aspect of the present invention, an insulating material layer covers the non-pixel area excluding the alignment mark.

In another aspect of the present invention, an insulating material layer covers the non-pixel area excluding the alignment mark and a surrounding area close to the alignment mark.

In still another aspect of the present invention, the non-pixel area does not comprise insulating layer material. According to the present invention, a liquid crystal display (LCD) device comprising a liquid crystal panel and a backlight module opposite to the liquid crystal panel is provided. The liquid crystal panel comprises a color filter substrate, a thin film transistor (TFT) array substrate and a liquid crystal layer between the color filter substrate and the TFT array substrate. The TFT array substrate comprises: a transparent substrate, comprising a non-pixel area and a pixel area; a plurality of TFTs arranged in array in the pixel area; and an alignment mark in the non-pixel area.

In one aspect of the present invention, an insulating material layer covers the non-pixel area excluding the alignment mark.

In another aspect of the present invention, an insulating material layer covers the non-pixel area excluding the alignment mark and a surrounding area close to the alignment mark.

In still another aspect of the present invention, the non-pixel area does not comprise insulating layer material.

The present invention eliminates any insulating material layers on the alignment marks by etching insulating material layers on the alignment marks so that it is capable of preventing from an alignment difference caused by a film-color difference between the second and the fourth insulating material layers on the alignment marks caused by uneven film thickness if the distance between the alignment marks in non-pixel area and the brink of the transparent substrate is narrower than insulating material protecting area (i.e. the alignment marks are out of the insulating material layer protecting area).

### BRIEF DESCRIPTION OF THE DRAWINGS

FIG. 1 shows an LCD device having a TFT array substrate according to the present invention.

FIG. 2 shows a transparent substrate according to the present invention.

FIG. 3 shows a TFT array substrate according to a first embodiment of the present invention.

FIG. 4 shows a TFT array substrate according to a second embodiment of the present invention.

FIG. 5 shows a TFT array substrate according to a third embodiment of the present invention.

### DETAILED DESCRIPTION OF THE PREFERRED EMBODIMENTS

The accompanying drawings are included to provide a further understanding of the invention, and are incorporated in and constitute a part of this specification. The drawings illustrate embodiments of the invention and, together with the description, serve to explain the principles of the invention.

FIG. 1 is a structure diagram of an LCD with a TFT array substrate according to the present invention.

Please refer to FIG. 1, the LCD with the TFT array substrate according to the present invention comprises a liquid crystal panel 10 and a backlight module 60 opposite to the liquid crystal panel 10. The backlight module 60 provides a display light source to the liquid crystal panel 10, and the liquid crystal panel 10 displays images through the display light source from the backlight module 60. The liquid crystal panel 10 comprises a color filter substrate 11, a TFT array substrate 12 and a liquid crystal layer 13 between the color filter substrate 11 and the TFT array substrate 12.

The color filter substrate 11 opposite to the TFT array substrate 12 generally comprises a transparent substrate (like glass substrate) and black matrix pictures, chromatic photoresist layer (like red, green and blue filter pictures) and alignment layer, etc, on the transparent substrate. The color filter substrate 11 according to the present invention is the same with the color filter substrate in the prior art, and therefore the detailed structure of the color filter substrate 11 refers to the relative technology. In hence, it is no further described.

The TFT array substrate 12 is mainly used for providing driving voltage to liquid crystal molecules in the liquid crystal layer 13 to being deflected for light passing through the liquid crystal layer 13 to coordinate with the color filter substrate 11 so that the liquid crystal panel displays images. The detail is in the following embodiments of the TFT array substrate 12.

### Embodiment 1

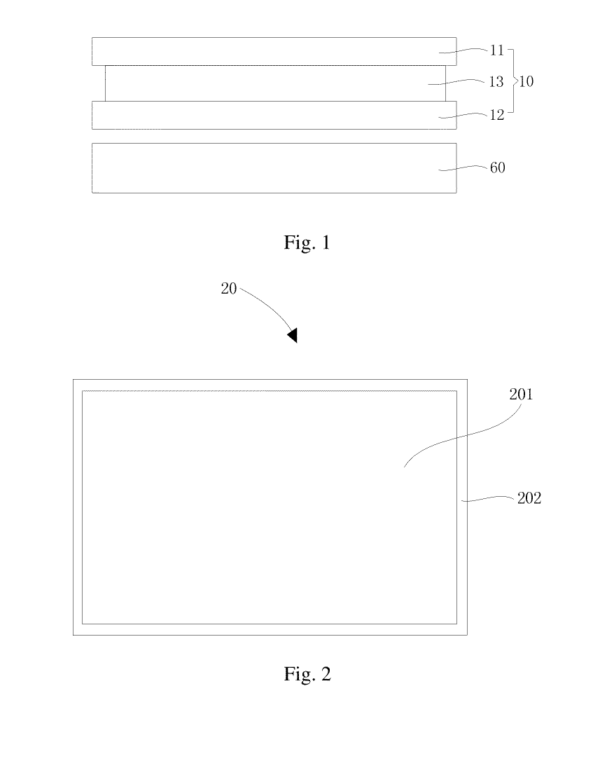

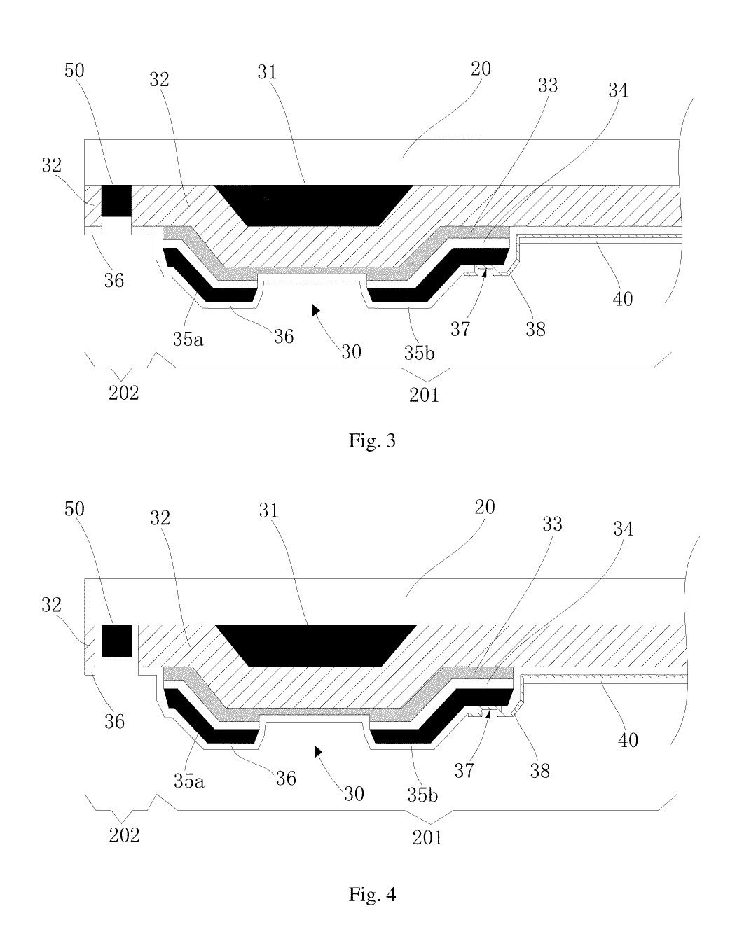

FIG. 2 is a diagram of a transparent substrate according to the present invention. FIG. 3 is a structure diagram of the TFT array substrate of the first embodiment according to the present invention.

Please refer to FIG. 2 and FIG. 3, the TFT array substrate 12 comprises a transparent substrate (like glass substrate) 20, a plurality of TFTs 30 on transparent substrate 20 and an alignment film 40.

Specifically, the transparent substrate 20 is divided into a pixel area 201 and a non-pixel area 202. The plurality of TFTs 30 are arranged in array in the pixel area 201 and comprises the following items on the transparent substrate 20 in order: a gate 31, a gate insulating layer 32 (also called a second insulating film layer or a second insulating material layer), an active layer formed by an amorphous silicon layer 33 and an ohmic contact layer 34, a source 35a (metal layer) and a drain 35b (metal layer) on the active layer, a passivation layer 36 (also called a fourth insulating film layer or a fourth insulating material layer), a passivation layer hole 37 formed on the passivation layer 36 and on the drain 35b, and a transparent pixel electrode 38 (i.e. Indium Tin

Oxide electrode). The alignment film 40 is set up on the transparent pixel electrode 38 but not covering the part of transparent pixel electrode 38 in the passivation layer hole 37.

The alignment mark 50, square in cross section picture, of the embodiment arranged in the non-pixel area 202 is usually produced by gate metal forming the gate 31 of the TFTs 30. The insulating material respectively forming the gate insulating layer 32 and the passivation layer 36 (like SiNx, etc.) in the process of forming the gate insulating layer 32 and the passivation layer 36 (like SiNx, etc.) covers the alignment mark 50.

In order to eliminate the insulating material covering the alignment mark 50, it pastes photoresist to the insulating material layer covering the alignment mark 50 and then exposes the pasted photoresist with the first alignment mark light shield. During exposure, it uses ultra violet-ray (UV) through the alignment mark light shield to irradiate the pasted photoresist. The photoresist sensitizes UV, and the part of which transforms from neutrality to acidity after UV exposure and the rest of which remains neutral. In the embodiment, the photoresist on the alignment mark 50 is exposed and the rest of the photoresist is not. In order to eliminate the fully exposed photoresist (i.e. the photoresist from neutrality to acidity), it develops the exposed photoresist. For instance, it eliminates the fully exposed photoresist by alkaline developer and turns out to expose the insulating material layer on the alignment mark 50. It takes methods like dry etching for eliminating unnecessary insulating material layer (i.e. exposed insulating material layer). Then, it eliminates the above un-exposed photoresist so that the alignment mark 50 is not covered by the insulating material layer, and on the contrary, the zone of the non-pixel area 202 except the alignment mark 50 is covered by the insulating material layer. That is to say that the insulating material layer covers part of the non-pixel area 202.

Furthermore, a shape of a cross-section of the alignment mark 50 according to the present invention is not limited in FIG. 2, and thus it is able to be crisscross, triangle or circle, etc.

The alignment mark 50 which is not covered by any insulating material layer is exposed because the insulating material layer on the alignment mark 50 is removed. Therefore, it prevents from an alignment difference caused by a film-color difference between the second and the fourth insulating material layers on the alignment marks caused by uneven film thickness if the distance between the alignment mark 50 in the non-pixel area 202 and the brink of the transparent substrate 20 is narrower than insulating material protecting area (i.e. the alignment mark 50 is out of the insulating material layer protecting area).

### Embodiment 2

FIG. 4 is a structure diagram of the TFT array substrate of the second embodiment according to the present invention.

Refer to FIG. 4. The difference between the first embodiment and second embodiment is that to eliminate the insulating material covering the alignment mark 50, it pastes photoresist to the insulating material layer covering the alignment mark 50 and then exposes the pasted photoresist with the second alignment mark light shield. During exposure, it uses ultra violet-ray (UV) through the alignment mark light shield to irradiate the pasted photoresist. The photoresist sensitizes UV, and the part of which transforms from neutrality to acidity after UV exposure and the rest of which remains neutral. In the embodiment, the photoresist on the alignment mark 50 and on the surrounding area close to the alignment mark 50 is exposed and the rest of the photoresist is not. In order to eliminate the fully exposed photoresist (i.e. the photoresist from neutrality to acidity), it develops the exposed photoresist. For instance, it eliminates the fully exposed photoresist by alkaline developer and turns out to expose the insulating material layer on the alignment mark 50 and on the surrounding area close to the alignment mark 50. It takes methods like dry etching for eliminating unnecessary insulating material layer (i.e. exposed insulating material layer). Then, it eliminates the above un-exposed photoresist so that the alignment mark 50 and the surrounding area close to the alignment mark 50 are not covered by the insulating material layer, and on the contrary, the zone of the non-pixel area 202 except the alignment mark 50 and the surrounding area close to the alignment mark 50 are covered by the insulating material layer. That is to say that the insulating material layer covers part of the non-pixel area 202.

The alignment mark 50 which is not covered by any insulating material layer is exposed because the insulating material layer on the alignment mark 50 and on the surrounding area close to the alignment mark 50 is removed. Therefore, it prevents from an alignment difference caused by a film-color difference between the second and the fourth insulation film layers on the alignment marks caused by uneven film thickness if the distance between the alignment mark 50 in the non-pixel area 202 and the brink of the transparent substrate 20 is narrower than insulating material layer protecting area (i.e. the alignment mark 50 is out of the insulating material layer protecting area).

### Embodiment 3

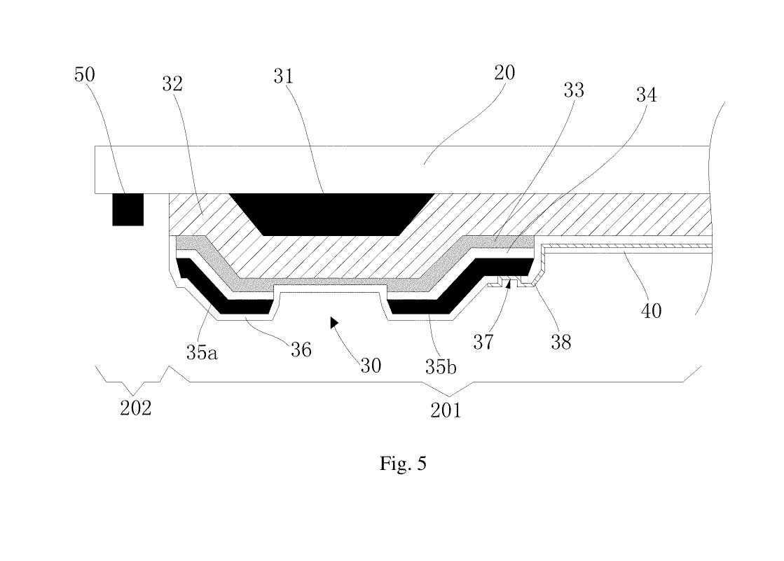

FIG. 5 is a structure diagram of the TFT array substrate of the third embodiment according to the present invention.

Refer to FIG. 5. The difference between the third embodiment and the second embodiment or the second embodiment is that to eliminate the insulating material covering the alignment mark 50, it pastes photoresist to the non-pixel area 202 and then exposes the pasted photoresist with the third alignment mark light shield. During exposure, it uses ultra violet-ray (UV) through the alignment mark light shield to irradiate the pasted photoresist. The photoresist sensitizes UV, and the part of which transforms from neutrality to acidity after UV exposure and the rest of which remains neutral. In the embodiment, the photoresist on the non-pixel area 202 is completely exposed. In order to eliminate the fully exposed photoresist (i.e. the photoresist from neutrality to acidity), it develops the exposed photoresist. For instance, it eliminates the fully exposed photoresist by alkaline developer and turns out to eliminate the photoresist on the non-pixel area 202 completely so that the insulating material layer on the non-pixel area 202 is fully exposed. For eliminating unnecessary insulating material layer (i.e. exposed insulating material layer), it takes methods like dry etching to eliminate the above un-exposed photoresist so that the non-pixel area 202 is not covered by the insulating material layer at all, and the alignment mark 50 is exposed thus. In other words, the insulating material layer on the non-pixel area 202 is totally removed.

The alignment mark 50 is exposed because the insulating material layer on the whole non-pixel area 202 is removed. Therefore, it prevents from an alignment difference caused by a film-color difference between the second and the fourth insulation film layers on the alignment marks caused by uneven film thickness if the distance between the alignment mark 50 in the non-pixel area 202 and the brink of the transparent substrate 20 is narrower than insulating material protecting area (i.e. the alignment mark 50 is out of the insulating material layer protecting area).

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A thin film transistor (TFT) array substrate comprising:
a transparent substrate, comprising a non-pixel area and a pixel area;
a plurality of TFTs arranged in array in the pixel area; and
an alignment mark in the non-pixel area.

2. The TFT array substrate of claim 1, wherein an insulating material layer covers the non-pixel area excluding the alignment mark.

3. The TFT array substrate of claim 1, wherein an insulating material layer covers the non-pixel area excluding the alignment mark and a surrounding area close to the alignment mark.

4. The TFT array substrate of claim 1, wherein the non-pixel area does not comprise insulating layer material.

5. A liquid crystal panel comprising a color filter substrate, a thin film transistor (TFT) array substrate and a liquid crystal layer between the color filter substrate and the TFT array substrate, the TFT array substrate comprising:
a transparent substrate, comprising a non-pixel area and a pixel area;
a plurality of TFTs arranged in array in the pixel area; and
an alignment mark in the non-pixel area.

6. The liquid crystal panel of claim 5, wherein an insulating material layer covers the non-pixel area excluding the alignment mark.

7. The liquid crystal panel of claim 5, wherein an insulating material layer covers the non-pixel area excluding the alignment mark and a surrounding area close to the alignment mark.

8. The liquid crystal panel of claim 5, wherein the non-pixel area does not comprise insulating layer material.

9. A liquid crystal display (LCD) device, comprising a liquid crystal panel and a backlight module opposite to the liquid crystal panel, the liquid crystal panel comprising a color filter substrate, a thin film transistor (TFT) array substrate and a liquid crystal layer between the color filter substrate and the TFT array substrate, the TFT array substrate comprising:
a transparent substrate, comprising a non-pixel area and a pixel area;
a plurality of TFTs arranged in array in the pixel area; and
an alignment mark in the non-pixel area.

10. The LCD device of claim 9, wherein an insulating material layer covers the non-pixel area excluding the alignment mark.

11. The LCD device of claim 9, wherein an insulating material layer covers the non-pixel area excluding the alignment mark and a surrounding area close to the alignment mark.

12. The LCD device of claim 9, wherein the non-pixel area does not comprise insulating layer material.
